(19) United States
(12) Patent Application Publication
(10) Pub. No.: US 2026/0120733 A1
(43) Pub. Date: Apr. 30, 2026

(54) BUFFER CIRCUIT AND MEMORY

(71) Applicant: CXMT Corporation, Hefei City (CN)

(72) Inventors: Gaoyuan PANG, Hefei City (CN); YOONJOO EOM, Hefei City (CN)

(73) Assignee: CXMT Corporation, Hefei City (CN)

(21) Appl. No.: 19/432,941

(22) Filed: Dec. 25, 2025

Related U.S. Application Data
(63) Continuation of application No. PCT/CN2024/102395, filed on Jun. 28, 2024.

(30) Foreign Application Priority Data
Jul. 3, 2023 (CN) 202310814094.5

(51) Int. Cl. G11C 8/06; G11C 8/10; H03K 5/24; H03K 19/0185; H03K 19/20

(52) U.S. Cl. CPC G11C 8/06; G11C 8/10; H03K 5/24; H03K 19/018521; H03K 19/20

(57) ABSTRACT

Each of a CA0 buffer circuit, a CA1 buffer circuit, a CA2 buffer circuit, a CA3 buffer circuit, and a CA4 buffer circuit includes: a first command address input terminal, connected to a command address pin, where different CA buffer circuits are connected to different command address pins; a first circuit output terminal, outputting a digital signal; a first comparator, a positive input terminal being connected to the first command address input terminal, a negative input terminal receiving a reference signal, an enable terminal receiving a power-down enable signal, an output terminal being connected to the first circuit output terminal, and the first comparator being turned off based on a level of the power-down enable signal after the memory enters a power-down mode; and a first voltage output circuit, outputting a high-level voltage or a low-level voltage to the first circuit output terminal after the memory enters the power-down mode.

### CROSS-REFERENCE TO RELATED APPLICATIONS

This application is a continuation of International Patent Application No. PCT/CN2024/102395, filed on Jun. 28, 2024, which claims priority to Chinese Patent Application No. 202310814094.5, filed on Jul. 3, 2023. The disclosures of the above-referenced applications are hereby incorporated by reference in their entirety.

### TECHNICAL FIELD

This application relates to the field of integrated circuit technologies, and in particular, to a buffer circuit and a memory.

### BACKGROUND

In the specification (specification, SPEC) of a fifth-generation double data rate memory (Double Data Rate, DDR5), in a power-down (power-down) mode, all command address (CA) buffer circuits need to be turned off to reduce power consumption. In addition, after the CA buffer circuits are turned off, it is still necessary to enable the memory to correctly receive a power-down exit (power-down exit, PDE) command to exit the power-down mode.

However, after the CA buffer circuits are turned off, the PDE command cannot be identified next time the PDE command is sent. Based on this, special disposition is required to identify the PDE command in the power-down mode.

### SUMMARY

Based on this, embodiments of this application provide a buffer circuit that can identify a PDE command in a power-down mode and a memory.

A buffer circuit is provided, is applied to a memory, and includes a CA0 buffer circuit, a CA1 buffer circuit, a CA2 buffer circuit, a CA3 buffer circuit, and a CA4 buffer circuit. Each of the CA0 buffer circuit, the CA1 buffer circuit, the CA2 buffer circuit, the CA3 buffer circuit, and the CA4 buffer circuit includes:
a first command address input terminal, connected to a command address pin, where different CA buffer circuits are connected to different command address pins;
a first circuit output terminal, configured to output a digital signal;
a first comparator, a positive input terminal being connected to the first command address input terminal, a negative input terminal receiving a reference signal, an enable terminal receiving a power-down enable signal, an output terminal being connected to the first circuit output terminal, and the first comparator being turned off based on a level of the power-down enable signal after the memory enters a power-down mode; and
a first voltage output circuit, configured to output a high-level voltage or a low-level voltage to the first circuit output terminal after the memory enters the power-down mode.

In an embodiment, the first voltage output circuit includes:
a first pull-up circuit, connected to the first circuit output terminal, and configured to output the high-level voltage to the first circuit output terminal; and
a first pull-down circuit, connected to the first circuit output terminal, and configured to output the low-level voltage to the first circuit output terminal.

In an embodiment, the first pull-up circuit includes:
a first switch unit, one terminal being connected to the first circuit output terminal, and the other terminal being connected to the high-level voltage.

In an embodiment, the first switch unit includes:
a first P-type transistor, a gate being connected to the power-down enable signal, and a source being connected to the high-level voltage; and
a second P-type transistor, a gate being connected to a command address inversion signal, a source being connected to a drain of the first P-type transistor, and a drain being connected to the first circuit output terminal.

In an embodiment, the first pull-down circuit includes:
a second switch unit, one terminal being connected to the first circuit output terminal, and the other terminal being connected to the low-level voltage.

In an embodiment, the second switch unit includes:
a first N-type transistor, a gate being connected to a command address inversion signal, and a source being connected to the low-level voltage; and
a second N-type transistor, a gate being connected to an inverted power-down enable signal, a source being connected to a drain of the first N-type transistor, and a drain being connected to the first circuit output terminal, where the inverted power-down enable signal is opposite to the power-down enable signal in level.

In an embodiment, the buffer circuit further includes a CA12 buffer circuit and a CA13 buffer circuit.

The CA12 buffer circuit includes:
a second command address input terminal, connected to a CA12 pin;
a second circuit output terminal, configured to output a digital signal;
a second comparator, a positive input terminal being connected to the second command address input terminal, a negative input terminal being configured to input a reference signal, an output terminal being connected to the second circuit output terminal, and an enable terminal being connected to a second enable signal, where a level of the second enable signal is a high level when the memory exits the power-down mode and is in a non-mirror mode, and is a low level in another case; and
a second voltage output circuit, configured to output the high-level voltage or the low-level voltage to the second circuit output terminal after the memory enters the power-down mode.

The CA13 buffer circuit includes:
a third command address input terminal, connected to a CA13 pin;
a third circuit output terminal, configured to output a digital signal;
a third comparator, a positive input terminal being connected to the third command address input terminal, a negative input terminal being configured to input a reference signal, an output terminal being connected to the third circuit output terminal, and an enable terminal being connected to a third enable signal, where a level of the third enable signal is a high level when the memory exits the power-down mode and is in a mirror mode, and is a low level in another case; and
a third voltage output circuit, configured to output the high-level voltage or the low-level voltage to the third circuit output terminal after the memory enters the power-down mode.

In an embodiment, the CA12 buffer circuit further includes a NOR gate. Two input terminals of the NOR gate are respectively connected to the inverted power-down enable signal and a mirror enable signal, and an output terminal is configured to output the second enable signal to the enable terminal of the second comparator.

In an embodiment, the CA13 buffer circuit further includes an AND gate. Two output terminals of the AND gate are respectively connected to a power-down enable signal and a mirror enable signal, and an output terminal is configured to output the third enable signal to the enable terminal of the third comparator.

In an embodiment, the second voltage output circuit includes a second pull-up circuit and a second pull-down circuit.

The second pull-up circuit includes:
a third P-type transistor, a gate being connected to the power-down enable signal, and a source being connected to the high-level voltage; and
a fourth P-type transistor, a gate being connected to a command address inversion signal, a source being connected to a drain of the third P-type transistor, and a drain being connected to the second circuit output terminal.

The second pull-down circuit includes:
a third N-type transistor, a gate being connected to a command address inversion signal, and a source being connected to the low-level voltage;
a fourth N-type transistor, a gate being connected to an inverted power-down enable signal, a source being connected to a drain of the third N-type transistor, and a drain being connected to the second circuit output terminal, where the inverted power-down enable signal is opposite to the power-down enable signal in level; and
a fifth N-type transistor, a gate being connected to a mirror enable signal, a source being connected to the low-level voltage, and a drain being connected to the second circuit output terminal.

In an embodiment, the third voltage output circuit includes a third pull-up circuit and a third pull-down circuit.

The third pull-up circuit includes:
a fifth P-type transistor, a gate being connected to the power-down enable signal, and a source being connected to the high-level voltage; and
a sixth P-type transistor, a gate being connected to a command address inversion signal, a source being connected to a drain of the fifth P-type transistor, and a drain being connected to the third circuit output terminal.

The third pull-down circuit includes:
a sixth N-type transistor, a gate being connected to a command address inversion signal, and a source being connected to the low-level voltage;
a seventh N-type transistor, a gate being connected to an inverted power-down enable signal, a source being connected to a drain of the sixth N-type transistor, and a drain being connected to the third circuit output terminal, where the inverted power-down enable signal is opposite to the power-down enable signal in level; and
an eighth N-type transistor, a gate being connected to an inverted mirror enable signal, a source being connected to the low-level voltage, and a drain being connected to the third circuit output terminal, where the inverted mirror enable signal is opposite to the mirror enable signal in level.

In an embodiment, the buffer circuit further includes CA5 to CA11 buffer circuits. The CA5 to CA11 buffer circuits are the same as the CA0 to CA4 buffer circuits in circuit structure.

A memory is provided, and includes:
the buffer circuit according to any item described above;
a command address buffer control circuit, connected to the buffer circuit, and configured to output a power-down enable signal to the buffer circuit; and
a decoder circuit, connected to the command address buffer control circuit, and configured to send a power-down exit command to the command address buffer control circuit.

In an embodiment, the memory further includes:
an address mirror circuit, connected to the buffer circuit, and configured to send a mirror enable signal to the buffer circuit.

In an embodiment, the memory further includes:
a command address inversion pin, connected to the buffer circuit, and configured to send a command address inversion signal to the buffer circuit.

In the buffer circuit and the memory, each of the CA0 to CA4 buffer circuits is provided with the first voltage output circuit. Therefore, after the memory enters the power-down mode and all the CA buffer circuits are turned off, each of the CA0 to CA4 buffer circuits can still output the high-level voltage or the low-level voltage to the first circuit output terminal through the first voltage output circuit, so that the first circuit output terminal can still output the digital signal even when the first comparator is turned off. In this case, after low-level data is applied to a CS_N pin, digital signal data output by the first voltage output circuit of each of the CA0 to CA4 buffer circuits and the data on the CS_N pin are combined to form a power-down exit command that conforms to the SPEC truth table of the memory (for example, a DDR5), so that the memory can exit the power-down mode.

### BRIEF DESCRIPTION OF DRAWINGS

To describe the technical solutions in the embodiments of this application or the conventional technologies more clearly, the following briefly describes the accompanying drawings required for describing the embodiments or the conventional technologies. Clearly, the accompanying drawings in the following description show merely some embodiments of this application, and a person of ordinary skill in the art may still derive other drawings from these accompanying drawings without creative efforts.

FIG. 1 is a block diagram of modules of a memory according to an embodiment;

FIG. 2 is a block diagram of modules of a memory according to another embodiment;

FIG. 3 shows a circuit structure of each of CA0 to CA4 buffer circuits according to an embodiment;

FIG. 4 shows a circuit structure of a CA12 buffer circuit according to an embodiment;

FIG. 5 shows a circuit structure of a CA13 buffer circuit according to an embodiment;

FIG. 6 shows a circuit structure of a NOR gate in a CA12 buffer circuit according to an embodiment; and

FIG. 7 shows a circuit structure of an AND gate in a CA13 buffer circuit according to an embodiment.

### DESCRIPTIONS OF REFERENCE NUMERALS

100—buffer circuit; 111—first command address input terminal; 112—first circuit output terminal; 113—first comparator; 114—first voltage output circuit; 1141—first pull-up circuit; 1142—first pull-down circuit; 121—second command address input terminal; 122—second circuit output terminal; 123—second comparator; 124—second voltage output circuit; 1241—second pull-up circuit; 1242—second pull-down circuit; 125—NOR gate; 131—third command address input terminal; 132—third circuit output terminal; 133—third comparator; 134—third voltage output circuit; 1341—third pull-up circuit; 1342—third pull-down circuit; 135—AND gate; 200—command address buffer control circuit; 300—decoder circuit; 400—address mirror circuit; and 500—command address inversion pin.

### DESCRIPTION OF EMBODIMENTS

For ease of understanding of this application, this application is described more comprehensively below with reference to related accompanying drawings. Embodiments of this application are provided in the accompanying drawings. However, this application may be implemented in many different forms, and is not limited to the embodiments described herein. Instead, these embodiments are provided to make the content of this application more thorough and comprehensive.

Unless otherwise defined, all technical and scientific terms used in the specification have meanings the same as those commonly understood by a person skilled in the art of this application. In this application, terms used in the specification of this application are merely intended to describe objectives of specific embodiments, but are not intended to limit this application.

It can be understood that the terms “first”, “second”, and the like adopted in this application may be adopted to describe various elements in the specification, but these elements are not limited to these terms. These terms are adopted only to distinguish a first element from another element.

It can be understood that the “connection” in the following embodiments is understood as “electrical connection”, “communication connection”, and the like if there is transfer of electrical signals or data between connected circuits, modules, units, and the like.

It can be understood that “at least one” refers to one or more, and “multiple” refers to two or more. “At least a part of an element” means a part of the element or the entire element.

As adopted herein, the singular forms of “a”, “an”, and “the” may also intended to include plural forms unless otherwise clearly specified in the context. It should also be understood that the term “comprise/include” or “have” specifies the presence of the stated features, entireties, steps, operations, components, portions or combinations thereof, but does not rule out the possibility of the presence or addition of one or more other features, entireties, steps, operations, components, portions or combinations thereof. Moreover, as employed in the specification, the term “and/or” includes any and all combinations of the related items listed.

In an embodiment, a memory is provided. The memory may include but is not limited to a fifth-generation double data rate memory (DDR5).

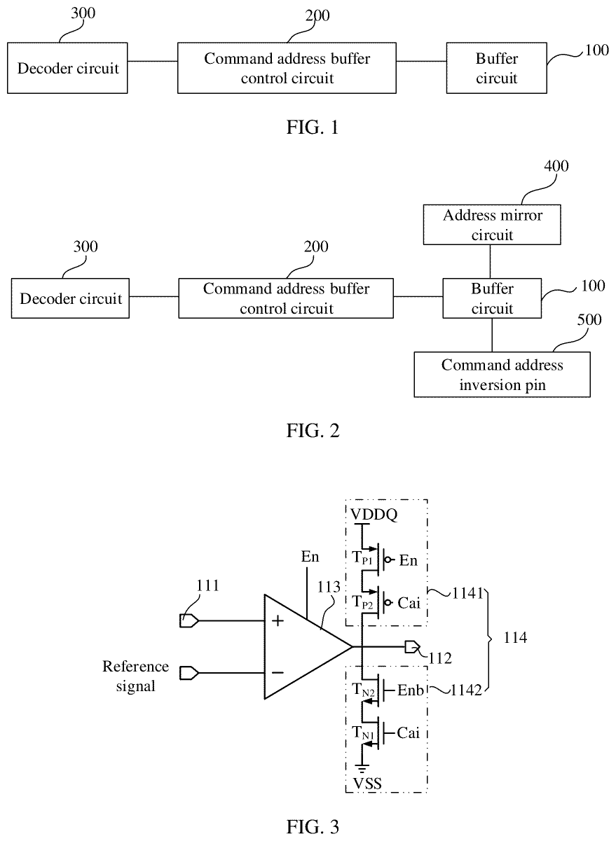

Refer to FIG. 1. The memory includes a buffer circuit 100, a command address buffer control circuit 200, and a decoder circuit 300. In addition, the memory may include multiple command address (CA) pins.

In the buffer circuit 100, one CA buffer circuit may be correspondingly disposed for each of the CA pins.

In an example, in the DDR5, the memory has 14 CA pins (CA0 to CA13 pins). Correspondingly, in the buffer circuit 100, 14 CA buffer circuits are correspondingly disposed (CA0 to CA13 buffer circuits).

In addition, a chip select signal (CS_N) pin is further disposed in the DDR5, and different CA pins may output different data through CA buffer circuits corresponding thereto. According to the SPEC truth table of the DDR5, the data output by the CA buffer circuits corresponding to the CA pins is combined with data on the CS_N pin to form a specific command. In addition, different data combinations may form different commands.

For example, it can be learned from the SPEC truth table shown in the following Table 1 that, when the data on the CS_N pin corresponds to a low level L, and data output by CA buffer circuits (that is, CA0 to CA4 buffer circuits) corresponding to CA0 to CA4 pins corresponds to a high level H, it indicates a “power-down exit” command. In addition, it can be understood that, in this case, a level corresponding to data output by CA buffer circuits (that is, CA5 to CA13 buffer circuits) corresponding to CA5 to CA13 pins is V, it represents that the data output by the CA buffer circuits corresponding to the CA5 to CA13 pins may correspond to the high level H or may correspond to the low level L.

TABLE 1

| | Pin | | | | | | |
|---|---|---|---|---|---|---|---|
| Mode state | CS_N | CA0 | CA1 | CA2 | CA3 | CA4 | CA5 |
| Power-down entry | L | H | H | H | L | H | V |
| Power-down exit | L | H | H | H | H | H | V |

| | Pin | | | | | | | |
|---|---|---|---|---|---|---|---|---|
| Mode state | CA6 | CA7 | CA8 | CA9 | CA10 | CA11 | CA12 | CA13 |
| Power-down entry | V | V | V | V | H | ODT = L | V | V |
| Power-down exit | V | V | V | V | V | V | V | V |

The command address buffer control circuit 200 is connected to the buffer circuit 100, and may generate and output a power-down enable signal En to the buffer circuit 100.

In an example, the command address buffer control circuit 200 may further generate and output an inverted power-down enable signal Enb to the buffer circuit 100. The inverted power-down enable signal Enb is opposite to the power-down enable signal En in level. When the level of the power-down enable signal En is a high level, the level of the inverted power-down enable signal Enb is a low level. When the level of the power-down enable signal En is a low level, the level of the inverted power-down enable signal Enb is a high level.

The decoder circuit 300 is connected to the command address buffer control circuit 200, and is configured to send a power-down exit command to the command address buffer control circuit 200.

The command address buffer control circuit 200 may generate a power-down enable signal En at a high level and an inverted power-down enable signal Enb at a low level when receiving the power-down exit command decoded by the decoder circuit 300.

In addition, in an example, the decoder circuit 300 may also send a power-down entry command to the command address buffer control circuit 200.

The command address buffer control circuit 200 may generate a power-down enable signal En at a low level and an inverted power-down enable signal Enb at a high level after receiving the power-down entry command decoded by the decoder circuit 300.

In an embodiment, refer to FIG. 2. The memory may further include an address mirror circuit 400. The address mirror circuit 400 is connected to the buffer circuit 100, and is configured to send a mirror enable signal Mir to the buffer circuit 100. When the level of the mirror enable signal Mir is a high level, it represents that the memory enters a mirror mode. When the level of the mirror enable signal Mir is a low level, it represents that the memory enters a non-mirror mode.

In an example, the address mirror circuit 400 may further send an inverted mirror enable signal Mirb to the buffer circuit 100. The inverted mirror enable signal Mirb is opposite to the mirror enable signal Mir in level.

The memory may further include a mirror (MIR) pin. An input terminal of the address mirror circuit 400 may be connected to the mirror (MIR) pin.

When the MIR pin is connected to a power supply voltage VDDQ, it represents that the memory is about to enter the mirror mode. In this case, the address mirror circuit 400 may generate and send a mirror enable signal Mir at a high level to the buffer circuit 100, and may generate and send an inverted mirror enable signal Mirb at a low level to the buffer circuit 100.

In addition, an even-numbered CA buffer circuit may be mirror-swapped with a subsequent odd-numbered CA buffer circuit in the memory for use. For example, the CA2 buffer circuit may be mirror-swapped with the CA3 buffer circuit (not the CA1 buffer circuit) for use. The CA4 buffer circuit is mirror-swapped with the CA5 buffer circuit (not the CA3 buffer circuit) for use.

When the MIR pin is connected to a power supply voltage VSS, it represents that the memory is about to enter the non-mirror mode, not the mirror mode. In this case, the address mirror circuit 400 may generate and send a mirror enable signal Mir at a low level to the buffer circuit 100, and may generate and send an inverted mirror enable signal Mirb at a high level to the buffer circuit 100. In this case, the CA buffer circuits are not mirror-swapped for use.

It should also be noted that the SPEC of the DDR5 specifies that the CA13 pin serves as an R17 address bit only when the capacity is 64 Gb, or in a three-dimensional stacking process. When it is determined based on the capacity and the process that the CA13 pin does not need to be adopted, the CA13 buffer circuit may be normally turned off, thereby reducing circuit power consumption. In addition, when the memory enters the mirror mode, because the CA12 buffer circuit needs to be mirror-swapped with the CA13 buffer circuit for use, the CA12 buffer circuit may be normally turned off in this case.

In an embodiment, refer to FIG. 2. The memory may further include a command address inversion (CAI) pin 500. The command address inversion pin 500 is connected to the buffer circuit 100, and is configured to send a command address inversion signal Cai to the buffer circuit 100.

When the CAI pin is connected to the power supply voltage VDDQ, the command address inversion signal Cai sent to the buffer circuit 100 is a high-level signal, it represents that the memory is about to enter a command address inversion mode. In addition, signals output by all the CA buffer circuits in the SPEC truth table in the command address inversion mode are inverted. For example, when the memory is not in the command address inversion mode, in the SPEC truth table, when the data on the CS_N pin corresponds to the low level L, and the data output by the CA buffer circuits (that is, the CA0 to CA4 buffer circuits) corresponding to the CA0 to CA4 pins corresponds to the high level H, it indicates the “power-down exit” command. When the memory enters the command address inversion mode, in the SPEC truth table, when the data on the CS_N pin corresponds to the low level L, and the data output by the CA buffer circuits (that is, the CA0 to CA4 buffer circuits) corresponding to the CA0 to CA4 pins corresponds to the low level L, it indicates the “power-down exit” command.

When the CAI pin is connected to the power supply voltage VSS, the command address inversion signal Cai sent to the buffer circuit 100 is a low-level signal, it represents that the memory does not enter the command address inversion mode.

In an embodiment, a buffer circuit applied to the memory is provided.

The buffer circuit 100 includes a CA0 buffer circuit, a CA1 buffer circuit, a CA2 buffer circuit, a CA3 buffer circuit, and a CA4 buffer circuit.

Refer to FIG. 3. Each of the CA0 buffer circuit, the CA1 buffer circuit, the CA2 buffer circuit, the CA3 buffer circuit, and the CA4 buffer circuit includes a first command address input terminal 111, a first circuit output terminal 112, a first comparator 113, and a first voltage output circuit 114.

In addition, in an example, the buffer circuit further includes CA5 to CA11 buffer circuits. The CA5 to CA11 buffer circuits are the same as the CA0 to CA4 buffer circuits in circuit structure. Certainly, alternatively, some of the CA5 to CA11 buffer circuits (for example, the CA5 buffer circuit) may be the same as the CA0 to CA4 buffer circuits in circuit structure, and the remaining buffer circuits (for example, the CA6 to CA11 buffer circuits) are different from the CA0 to CA4 buffer circuits in circuit structure. Alternatively, all of the CA5 to CA11 buffer circuits are different from the CA0 to CA4 buffer circuits in circuit structure. This is not limited herein.

The first command address input terminal 111 is connected to a CA pin. Different CA buffer circuits are connected to different CA pins.

For example, the first command address input terminal 111 of the CA0 buffer circuit is connected to the CA0 pin. The first command address input terminal 111 of the CA1 buffer circuit is connected to the CA1 pin. The first command address input terminal 111 of the CA2 buffer circuit is connected to the CA2 pin. The first command address input terminal 111 of the CA3 buffer circuit is connected to the CA3 pin.

The first circuit output terminal 112 is configured to output a digital signal. The level of the digital signal output by the first circuit output terminal 112 may represent data output by the CA buffer circuit.

A positive input terminal of the first comparator 113 is connected to the first command address input terminal 111, to receive a voltage on the CA pin. In addition, a negative input terminal of the first comparator 113 receives a reference signal. In this case, an output terminal of the first comparator 113 may output a digital signal through comparison between an analog voltage on the CA pin and an analog voltage of the reference signal.

In addition, the output terminal of the first comparator 113 is connected to the first circuit output terminal 112, so that the first circuit output terminal 112 can output the digital signal.

An enable terminal of the first comparator 113 may be connected to the command address buffer control circuit 200, to receive a power-down enable signal En. The first comparator 113 may be turned off and on based on the level of the power-down enable signal En after the enable terminal thereof receives the power-down enable signal En.

For example, when the enable terminal of the first comparator 113 receives a power-down enable signal En at a high level, the first comparator 113 may be turned on. When the enable terminal of the first comparator 113 receives a power-down enable signal En at a low level, the first comparator 113 may be turned off.

After the memory enters the power-down mode, the command address buffer control circuit 200 may generate a power-down enable signal En at a low level, so that the first comparator 113 is turned off based on the level of the power-down enable signal.

After the memory exits the power-down mode, the command address buffer control circuit 200 may generate a power-down enable signal En at a high level, so that the first comparator 113 is turned on based on the level of the power-down enable signal.

The first voltage output circuit 114 is configured to output a high-level voltage or a low-level voltage to the first circuit output terminal after the memory enters the power-down mode.

As described above, after the memory enters the power-down mode, the first comparator 113 is turned off, so that the CA buffer circuit is turned off. In this case, the output terminal of the first comparator 113 cannot output a digital signal based on a comparison result that is between the voltage on the CA pin and the voltage of the reference signal and that is received by the positive input terminal of the first comparator 113. Therefore, the output terminal of the first comparator 113 cannot output a digital signal to the first circuit output terminal 112.

In this case, a high-level voltage or a low-level voltage is output to the first circuit output terminal 112 through the first voltage output circuit 114, so that the first circuit output terminal 112 can still output a digital signal even when the first comparator 113 is turned off.

Therefore, after low-level data is applied to the CS_N pin, the digital signal data output by the first voltage output circuit 114 of each of the CA0 to CA4 buffer circuits is combined with the data on the CS_N pin, to form the power-down exit command that conforms to the SPEC truth table of the memory (for example, a DDR5), and send the power-down exit command to the decoder circuit 300, so that the decoder circuit 300 can decode the power-down exit command, and sends the power-down exit command to the command address buffer control circuit 200. The command address buffer control circuit 200 may generate a power-down enable signal En at a high level after receiving the power-down exit command decoded by the decoder circuit 300, so that the first comparator 113 is turned on.

In an example, when the command address inversion mode and the mirror mode are not enabled, if the memory already enters the power-down mode, the comparator in each of the CA buffer circuits is turned off. In this case, in the CA0 to CA4 buffer circuits, a high-level voltage (high-level voltage) may be output to the first circuit output terminal 112 through the first voltage output circuit 114, so that the digital signal output by the first circuit output terminal 112 is a high-level signal.

In this case, after the low-level data is applied to the CS_N pin, the digital signal data output by the first voltage output circuit 114 of each of the CA0 to CA4 buffer circuits and the data on the CS_N pin are combined to form the power-down exit command that conforms to the SPEC truth table of the memory (for example, the DDR5).

In another example, when the command address inversion mode is enabled but the mirror mode is not enabled, if the memory already enters the power-down mode, the comparator in each of the CA buffer circuits is turned off. In this case, in the CA0 to CA4 buffer circuits, the low-level voltage may be output to the first circuit output terminal 112 through the first voltage output circuit 114, so that the digital signal output by the first circuit output terminal 112 is a low-level signal.

In this case, after low-level data is applied to the CS_N pin, the digital signal data output by the first voltage output circuit 114 of each of the CA0 to CA4 buffer circuits is combined with the data on the CS_N pin to form the power-down exit command that conforms to the SPEC truth table in the command address inversion mode.

In an embodiment, refer to FIG. 3. The first voltage output circuit 114 includes a first pull-up circuit 1141 and a first pull-down circuit 1142.

The first pull-up circuit 1141 is connected to the first circuit output terminal 112, and is configured to output the high-level voltage to the first circuit output terminal 112.

The first pull-down circuit 1142 is connected to the first circuit output terminal 112, and is configured to output the low-level voltage to the first circuit output terminal 112.

In addition, the high-level voltage and the low-level voltage are output to the first circuit output terminal 112 through the first pull-up circuit 1141 and the first pull-down circuit 1142, respectively, thereby facilitating circuit control.

Certainly, in another embodiment, the first circuit output terminal 112 may be connected to the same signal output terminal of the first voltage output circuit 114 through circuit design of the first voltage output circuit 114. The signal output terminal may perform high-level voltage output when the high-level voltage needs to be output, or may perform low-level voltage output when the low-level voltage needs to be output.

In an embodiment, refer to FIG. 3. The first pull-up circuit 1141 includes a first switch unit. One terminal of the first switch unit is connected to the first circuit output terminal 112, and the other terminal is connected to the high-level voltage VDDQ.

The first switch unit may control output of the high-level voltage of the first pull-up circuit 1141.

In an example, the first switch unit may include a first P-type transistor T_{P1} and a second P-type transistor T_{P2}.

The source of the second P-type transistor T_{P2} is connected to the drain of the first P-type transistor T_{P1}.

In addition, the gate of the first P-type transistor T_{P1} is connected to a power-down enable signal En, and the source of the first P-type transistor T_{P1} is connected to the high-level voltage VDDQ. The gate of the second P-type transistor T_{P2} is connected to the command address inversion signal Cai, and the drain of the second P-type transistor T_{P2} is connected to the first circuit output terminal 112.

After the memory enters the power-down mode, the power-down enable signal En is at the low level. In this case, the first P-type transistor T_{P1} is turned on.

In addition, the command address inversion signal Cai is at a low level if the memory is not in the command address inversion mode. In this case, the second P-type transistor T_{P2} is turned on. Therefore, in this case, the high-level voltage VDDQ connected to the source of the first P-type transistor T_{P1} is transmitted to the first circuit output terminal 112, so that the first circuit output terminal 112 can output the high-level signal.

In this case, the high-level signal output by the first circuit output terminal 112 of each of the CA0 to CA4 buffer circuits may be combined with the low-level data on the CS_N pin, to form the power-down exit command that conforms to the SPEC truth table.

The command address inversion signal Cai is at a high level if the memory is in the command address inversion mode. In this case, the second P-type transistor T_{P2} is turned off. Therefore, in this case, the high-level voltage VDDQ connected to the source of the first P-type transistor T_{P1} is not transmitted to the first circuit output terminal 112. The first circuit output terminal 112 may receive the low-level signal provided by the first pull-down circuit 1142.

In this case, the low-level signal output by the first circuit output terminal 112 of each of the CA0 to CA4 buffer circuits may be combined with the low-level data on the CS_N pin, to form the power-down exit command that conforms to the SPEC truth table in the command address inversion mode.

After the memory exits the power-down mode, the power-down enable signal En is at the high level. In this case, the first P-type transistor T_{P1} is turned off. Therefore, regardless of whether the memory is in the command address inversion mode, the high-level voltage VDDQ connected to the source of the first P-type transistor T_{P1} is not transmitted to the first circuit output terminal 112. In addition, the first pull-down circuit 1142 may be configured to not output the low-level signal to the first circuit output terminal 112 based on that the power-down enable signal En is at the high level. In addition, after the memory exits the power-down mode, the first comparator 113 is turned on, so that the first circuit output terminal 112 can receive a voltage signal output by the first comparator 113 based on the CA pin.

In an embodiment, refer to FIG. 3. The first pull-down circuit 1142 includes a second switch unit. One terminal of the second switch unit is connected to the first circuit output terminal 112, and the other terminal is connected to the low-level voltage VSS. The low-level voltage VSS is, for example, a ground voltage.

The second switch unit may control output of the low-level voltage of the first pull-down circuit 1142.

In an example, the second switch unit may include a first N-type transistor T_{N1} and a second N-type transistor T_{N2}.

The source of the second N-type transistor T_{N2} is connected to the drain of the first N-type transistor T_{N1}.

In addition, the gate of the first N-type transistor T_{N1} is connected to the command address inversion signal Cai, and the source of the first N-type transistor T_{N1} is connected to the low-level voltage VSS. The gate of the second N-type transistor T_{N2} is connected to the inverted power-down enable signal Enb, and the drain of the second N-type transistor T_{N2} is connected to the first circuit output terminal 112.

After the memory enters the power-down mode, the inverted power-down enable signal Enb is at a high level. In this case, the second N-type transistor T_{N2} is turned on

In addition, the command address inversion signal Cai is at the high level if the memory is in the command address inversion mode. In this case, the first N-type transistor T_{N1} is turned on. Therefore, in this case, the low-level voltage VSS connected to the source of the first N-type transistor T_{N1} is transmitted to the first circuit output terminal 112, so that the first circuit output terminal 112 can output a low-level signal.

In this case, the low-level signal output by the first circuit output terminal 112 of each of the CA0 to CA4 buffer circuits may be combined with the low-level data on the CS_N pin, to form the power-down exit command that conforms to the SPEC truth table in the command address inversion mode.

The command address inversion signal Cai is at the low level if the memory is not in the command address inversion mode. In this case, the first N-type transistor T_{N1} is turned off. Therefore, in this case, the low-level voltage VSS connected to the source of the first N-type transistor T_{N1} is not transmitted to the first circuit output terminal 112. The first circuit output terminal 112 may receive the high-level signal provided by the first pull-up circuit 1141.

In this case, the high-level signal output by the first circuit output terminal 112 of each of the CA0 to CA4 buffer circuits may be combined with the low-level data on the CS_N pin, to form the power-down exit command that conforms to the SPEC truth table.

After the memory exits the power-down mode, the inverted power-down enable signal Enb is at a low level. In this case, the second N-type transistor T_{N2} is turned off. Therefore, regardless of whether the memory is in the command address inversion mode, the low-level voltage VSS connected to the source of the first N-type transistor T_{N1} is not transmitted to the first circuit output terminal 112. In addition, the first pull-up circuit 1141 may be configured to not output the high-level signal to the first circuit output terminal 112 based on that the inverted power-down enable signal Enb is at the high level. In addition, after the memory exits the power-down mode, the first comparator 113 is turned on, so that the first circuit output terminal 112 can receive a voltage signal output by the first comparator 113 based on the CA pin.

In an embodiment, the buffer circuit further includes a CA12 buffer circuit and a CA13 buffer circuit.

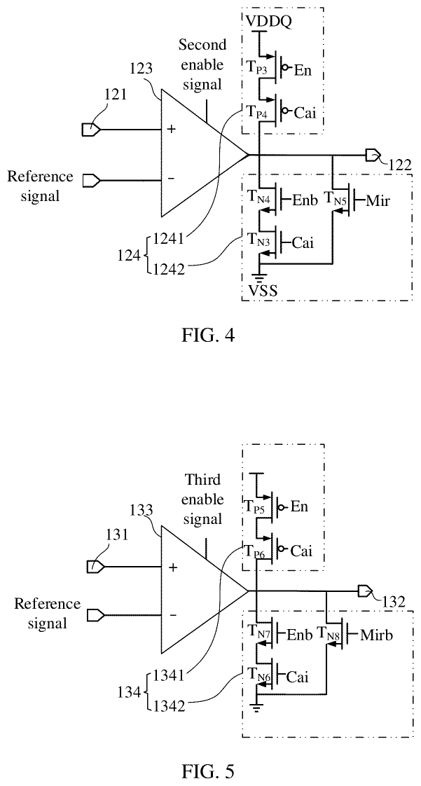

Refer to FIG. 4. The CA12 buffer circuit includes a second command address input terminal 121, a second circuit output terminal 122, a second comparator 123, and a second voltage output circuit 124.

The second command address input terminal 121 is connected to a CA12 pin. The second circuit output terminal 122 is configured to output a digital signal. The level of the digital signal output by the second circuit output terminal 122 may represent data output by the CA12 buffer circuit.

A positive input terminal of the second comparator 123 is connected to the second command address input terminal 121, to receive a voltage on the CA12 pin. A negative input terminal of the second comparator 123 is configured to input the reference signal. In this case, an output terminal of the second comparator 123 may output the digital signal through comparison between an analog voltage on the CA12 pin and the analog voltage of the reference signal.

In addition, the output terminal of the second comparator 123 is connected to the second circuit output terminal 122, so that the second circuit output terminal 122 can output the digital signal.

An enable terminal of the second comparator 123 is connected to a second enable signal. The level of the second enable signal is a high level when the memory exits the power-down mode and is in the non-mirror mode, and is a low level in another case. The second comparator 123 is turned on when the level of the second enable signal is a high level. The second comparator 123 is turned off when the level of the second enable signal is a low level. Therefore, in this case, the second comparator 123 is turned on only when the memory exits the power-down mode and is in the non-mirror mode. Otherwise, the second comparator 123 is turned off when the memory enters either the power-down mode or the mirror mode.

The second voltage output circuit 124 is configured to output a high-level voltage or a low-level voltage to the second circuit output terminal 122 after the memory enters the power-down mode.

Refer to FIG. 5. The CA13 buffer circuit includes a third command address input terminal 131, a third circuit output terminal 132, a third comparator 133, and a third voltage output circuit 134.

The third command address input terminal 131 is connected to a CA13 pin. The third circuit output terminal 132 is configured to output a digital signal. The level of the digital signal output by the third circuit output terminal 132 may represent data output by the CA13 buffer circuit.

A positive input terminal of the third comparator 133 is connected to the third command address input terminal 131, to receive a voltage on the CA13 pin. A negative input terminal of the third comparator 133 is configured to input the reference signal. In this case, an output terminal of the third comparator 133 may output the digital signal through comparison between an analog voltage on the CA13 pin and the analog voltage of the reference signal.

In addition, the output terminal of the third comparator 133 is connected to the third circuit output terminal 132, so that the third circuit output terminal 132 can output the digital signal.

An enable terminal of the third comparator 133 is connected to a third enable signal. The level of the third enable signal is a high level when the memory exits the power-down mode and is in the mirror mode, and is a low level in another case. The third comparator 133 is turned on when the level of the third enable signal is a high level. The third comparator 133 is turned off when the level of the third enable signal is a low level. Therefore, in this case, the third comparator 133 is turned on only when the memory exits the power-down mode and is in the mirror mode. Otherwise, the third comparator 133 is turned off when the memory enters either the power-down mode or the non-mirror mode.

The third voltage output circuit 134 is configured to output a high-level voltage or a low-level voltage to the third circuit output terminal 132 after the memory enters the power-down mode.

In this embodiment, the enable terminal of the second comparator 123 is connected to the second enable signal and the enable terminal of the third comparator 133 is connected to the third enable signal, so that both the CA12 buffer circuit and the CA13 buffer circuit can be turned off after the memory enters the power-down mode, thereby reducing power consumption.

In addition, after the memory exits the power-down mode, the CA12 buffer circuit is turned on and the CA13 buffer circuit is turned off if the memory is in the non-mirror mode, or the CA13 buffer circuit is turned on and the CA12 buffer circuit is turned off if the memory is in the mirror mode, so that the CA13 buffer circuit and the CA12 buffer circuit can be effectively mirror-swapped. In addition, when it is determined that the CA13 pin does not need to be adopted based on the capacity and the process, the CA13 buffer circuit may be normally turned off in the non-mirror mode and the CA12 buffer circuit mirror-swapped with the CA13 buffer circuit in the mirror mode can be normally turned off, thereby further reducing power consumption.

In addition, it is similar to dispose the first voltage output circuit 114 in each of the CA0 to CA4 buffer circuits, dispose the second voltage output circuit 124 in the CA12 buffer circuit, and dispose the third voltage output circuit 134 in the CA13 buffer circuit. In this case, in the non-mirror mode, the second circuit output terminal 122 can still output a digital signal even when the second comparator 123 is turned off because the memory enters the power-down mode. In addition, in the mirror mode, the third circuit output terminal 132 can still output a digital signal even when the third comparator 133 is turned off because the memory enters the power-down mode.

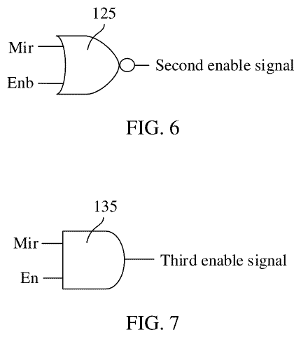

In an embodiment, refer to FIG. 6. The CA12 buffer circuit further includes a NOR gate 125. Two input terminals of the NOR gate 125 are respectively connected to an inverted power-down enable signal Enb and a mirror enable signal Mir, and an output terminal is configured to output a second enable signal to the enable terminal of the second comparator 123.

In this case, the level of the inverted power-down enable signal Enb is a high level when the memory enters the power-down mode, and is a low level when the memory exits the power-down mode. The level of the mirror enable signal Mir is a high level when the memory enters the mirror mode, and is a low level when the memory enters the non-mirror mode.

Therefore, in this case, it can be effectively ensured through disposition of the NOR gate 125 that the level of the second enable signal is a high level when the memory exits the power-down mode and is in the non-mirror mode, and is a low level in another case.

In an embodiment, refer to FIG. 7. The CA13 buffer circuit further includes an AND gate 135. Two output terminals of the AND gate 135 are respectively connected to a power-down enable signal En and a mirror enable signal Mir, and an output terminal is configured to output a third enable signal to the enable terminal of the third comparator 133.

In this case, the level of the power-down enable signal En is a low level when the memory enters the power-down mode, and is a high level when the memory exits the power-down mode. The level of the mirror enable signal Mir is a high level when the memory enters the mirror mode, and is a low level when the memory enters the non-mirror mode.

Therefore, in this case, it can be effectively ensured through disposition of the AND gate 135 that the level of the third enable signal is a high level when the memory exits the power-down mode and is in the mirror mode, and is a low level in another case.

In an embodiment, refer to FIG. 4. The second voltage output circuit 124 includes a second pull-up circuit 1241 and a second pull-down circuit 1242.

The second pull-up circuit 1241 includes a third P-type transistor T_{P3} and a fourth P-type transistor T_{P4}.

The gate of the third P-type transistor T_{P3} is connected to a power-down enable signal En, and the source of the third P-type transistor T_{P3} is connected to a high-level voltage VDDQ. The gate of the fourth P-type transistor T_{P4} is connected to a command address inversion signal Cai, the source of the fourth P-type transistor T_{P4} is connected to the drain of the third P-type transistor, and the drain of the fourth P-type transistor T_{P4} is connected to the second circuit output terminal 122.

An operating principle of the second pull-up circuit 1241 is similar to that of the first pull-up circuit 1141. Details are not described herein again.

The second pull-down circuit 1242 includes a third N-type transistor T_{N3}, a fourth N-type transistor T_{N4}, and a fifth N-type transistor T_{N5}.

The gate of the third N-type transistor T_{N3} is connected to a command address inversion signal Cai, and the source of the third N-type transistor T_{N3} is connected to a low-level voltage VSS. The gate of the fourth N-type transistor T_{N4} is connected to an inverted power-down enable signal Enb, the source of the fourth N-type transistor T_{N4} is connected to the drain of the third N-type transistor T_{N3}, and the drain of the fourth N-type transistor T_{N4} is connected to the second circuit output terminal 122.

An operating principle of the third N-type transistor T_{N3} of the second pull-down circuit 1242 is similar to that of the first N-type transistor T_{N1} of the first pull-down circuit 1241. An operating principle of the fourth N-type transistor T_{N4} of the second pull-down circuit 1242 is similar to that of the second N-type transistor T_{N2} of the first pull-down circuit 1241. Details are not described herein again.

The gate of the fifth N-type transistor T_{N5} is connected to a mirror enable signal Mir, the source of the fifth N-type transistor T_{N5} is connected to a low-level voltage VSS, and the drain of the fifth N-type transistor T_{N5} is connected to the second circuit output terminal 122.

The level of the mirror enable signal Mir is a high level when the memory enters the mirror mode, and is a low level when the memory enters the non-mirror mode. In addition, the low-level voltage VSS may be, for example, a ground voltage.

Therefore, when the memory enters the mirror mode, the second circuit output terminal 122 may be grounded through the fifth N-type transistor T_{N5}, thereby effectively reducing power consumption of the CA12 buffer circuit.

In an embodiment, refer to FIG. 5. The third voltage output circuit 134 includes a third pull-up circuit 1341 and a third pull-down circuit 1342.

The third pull-up circuit 1341 includes a fifth P-type transistor T_{P5} and a sixth P-type transistor T_{P6}.

The gate of the fifth P-type transistor T_{P5} is connected to a power-down enable signal En, and the source of the fifth P-type transistor T_{P5} is connected to the high-level voltage VDDQ.

The gate of the sixth P-type transistor T_{P6} is connected to a command address inversion signal Cai, the source of the sixth P-type transistor T_{P6} is connected to the drain of the fifth P-type transistor T_{P5}, and the drain of the sixth P-type transistor T_{P6} is connected to the third circuit output terminal 134.

An operating principle of the third pull-up circuit 1341 is similar to that of the first pull-up circuit 1141. Details are not described herein again.

The third pull-down circuit 1342 includes a sixth N-type transistor T_{N6}, a seventh N-type transistor T_{N7}, and an eighth N-type transistor T_{N8}.

The gate of the sixth N-type transistor T_{N6} is connected to a command address inversion signal Cai, and the source of the sixth N-type transistor T_{N6} is connected to a low-level voltage VSS. The gate of the seventh N-type transistor T_{N7} is connected to an inverted power-down enable signal Enb, the source of the seventh N-type transistor T_{N7} is connected to the drain of the sixth N-type transistor T_{N6}, and the drain of the seventh N-type transistor T_{N7} is connected to the third circuit output terminal 134.

An operating principle of the sixth N-type transistor T_{N6} of the third pull-down circuit 1342 is similar to that of the first N-type transistor T_{N1} of the first pull-down circuit 1241. An operating principle of the seventh N-type transistor T_{N7} of the second pull-down circuit 1242 is similar to that of the second N-type transistor T_{N2} of the first pull-down circuit 1241. Details are not described herein again.

The gate of the eighth N-type transistor T_{N8} is connected to an inverted mirror enable signal Mirb, the source of the eighth N-type transistor T_{N8} is connected to a low-level voltage VSS, and the drain of the eighth N-type transistor T_{N8} is connected to the third circuit output terminal 134.

The level of the inverted mirror enable signal Mirb is a low level when the memory enters the mirror mode, and is a high level when the memory enters the non-mirror mode. In addition, the low-level voltage VSS may be, for example, a ground voltage.

Therefore, when the memory enters the non-mirror mode, the third circuit output terminal 134 may be grounded through the eighth N-type transistor T_{N8}, thereby effectively reducing power consumption of the CA13 buffer circuit.

In the descriptions of the specification, descriptions with reference to terms such as “an embodiment” and “another embodiment” means that specific features, structures, materials, or features described with reference to the embodiment or example are included in at least one embodiment or example of this application. In the specification, a schematic description of the foregoing term does not necessarily refer to a same embodiment or example.

The technical features in the foregoing embodiments may be combined arbitrarily. For brevity of description, not all possible combinations of these technical features in the foregoing embodiments are described. However, as long as these combinations of technical features are not contradictory, they should all be considered within the scope described in the specification

The foregoing embodiments represent only several implementations of this application, and are described in a relatively specific and detailed way, but should not be construed as limitations on the patent scope of this application. It should be noted that a person of ordinary skill in the art can further make several variations and improvements without departing from the concept of this application, and these variations and improvements shall fall within the protection scope of this application. Therefore, the protection scope of this application shall be subject to the appended claims.

What is claimed is:

1. A buffer circuit, applied to a memory, and comprising a CA0 buffer circuit, a CA1 buffer circuit, a CA2 buffer circuit, a CA3 buffer circuit, and a CA4 buffer circuit, each of the CA0 buffer circuit, the CA1 buffer circuit, the CA2 buffer circuit, the CA3 buffer circuit, and the CA4 buffer circuit comprising:
a first command address input terminal, connected to a command address pin, wherein different CA buffer circuits are connected to different command address pins;
a first circuit output terminal, configured to output a digital signal;
a first comparator, a positive input terminal being connected to the first command address input terminal, a negative input terminal receiving a reference signal, an enable terminal receiving a power-down enable signal, an output terminal being connected to the first circuit output terminal, and the first comparator being turned off based on a level of the power-down enable signal after the memory enters a power-down mode; and
a first voltage output circuit, configured to output a high-level voltage or a low-level voltage to the first circuit output terminal after the memory enters the power-down mode.

2. The buffer circuit according to claim 1, wherein the first voltage output circuit comprises:
a first pull-up circuit, connected to the first circuit output terminal, and configured to output the high-level voltage to the first circuit output terminal; and
a first pull-down circuit, connected to the first circuit output terminal, and configured to output the low-level voltage to the first circuit output terminal.

3. The buffer circuit according to claim 2, wherein the first pull-up circuit comprises:
a first switch unit, one terminal being connected to the first circuit output terminal, and the other terminal being connected to the high-level voltage.

4. The buffer circuit according to claim 3, wherein the first switch unit comprises:
a first P-type transistor, a gate being connected to the power-down enable signal, and a source being connected to the high-level voltage; and
a second P-type transistor, a gate being connected to a command address inversion signal, a source being connected to a drain of the first P-type transistor, and a drain being connected to the first circuit output terminal.

5. The buffer circuit according to claim 2, wherein the first pull-down circuit comprises:
a second switch unit, one terminal being connected to the first circuit output terminal, and the other terminal being connected to the low-level voltage.

6. The buffer circuit according to claim 5, wherein the second switch unit comprises:
a first N-type transistor, a gate being connected to a command address inversion signal, and a source being connected to the low-level voltage; and
a second N-type transistor, a gate being connected to an inverted power-down enable signal, a source being connected to a drain of the first N-type transistor, and a drain being connected to the first circuit output terminal, wherein the inverted power-down enable signal is opposite to the power-down enable signal in level.

7. The buffer circuit according to claim 1, further comprising a CA12 buffer circuit and a CA13 buffer circuit;
the CA12 buffer circuit comprising:
a second command address input terminal, connected to a CA12 pin;
a second circuit output terminal, configured to output a digital signal;
a second comparator, a positive input terminal being connected to the second command address input terminal, a negative input terminal being configured to input a reference signal, an output terminal being connected to the second circuit output terminal, and an enable terminal being connected to a second enable signal, wherein a level of the second enable signal is a high level when the memory exits the power-down mode and is in a non-mirror mode, and is a low level in another case; and
a second voltage output circuit, configured to output the high-level voltage or the low-level voltage to the second circuit output terminal after the memory enters the power-down mode; and
the CA13 buffer circuit comprising:
a third command address input terminal, connected to a CA13 pin;
a third circuit output terminal, configured to output a digital signal;
a third comparator, a positive input terminal being connected to the third command address input terminal, a negative input terminal being configured to input a reference signal, an output terminal being connected to the third circuit output terminal, and an enable terminal being connected to a third enable signal, wherein a level of the third enable signal is a high level when the memory exits the power-down mode and is in a mirror mode, and is a low level in another case; and
a third voltage output circuit, configured to output the high-level voltage or the low-level voltage to the third circuit output terminal after the memory enters the power-down mode.

8. The buffer circuit according to claim 7, wherein the CA12 buffer circuit further comprises a NOR gate, two input terminals of the NOR gate being respectively connected to the inverted power-down enable signal and a mirror enable signal, and an output terminal being configured to output the second enable signal to the enable terminal of the second comparator.

9. The buffer circuit according to claim 7, wherein the CA13 buffer circuit further comprises an AND gate, two output terminals of the AND gate being respectively connected to a power-down enable signal and a mirror enable signal, and an output terminal being configured to output the third enable signal to the enable terminal of the third comparator.

10. The buffer circuit according to claim 7, wherein the second voltage output circuit comprises a second pull-up circuit and a second pull-down circuit;
the second pull-up circuit comprising:
a third P-type transistor, a gate being connected to the power-down enable signal, and a source being connected to the high-level voltage; and
a fourth P-type transistor, a gate being connected to a command address inversion signal, a source being connected to a drain of the third P-type transistor, and a drain being connected to the second circuit output terminal; and
the second pull-down circuit comprising:
a third N-type transistor, a gate being connected to a command address inversion signal, and a source being connected to the low-level voltage;
a fourth N-type transistor, a gate being connected to an inverted power-down enable signal, a source being connected to a drain of the third N-type transistor, and a drain being connected to the second circuit output terminal, wherein the inverted power-down enable signal is opposite to the power-down enable signal in level; and
a fifth N-type transistor, a gate being connected to a mirror enable signal, a source being connected to the low-level voltage, and a drain being connected to the second circuit output terminal.

11. The buffer circuit according to claim 7, wherein the third voltage output circuit comprises a third pull-up circuit and a third pull-down circuit;
the third pull-up circuit comprising:
a fifth P-type transistor, a gate being connected to the power-down enable signal, and a source being connected to the high-level voltage; and
a sixth P-type transistor, a gate being connected to a command address inversion signal, a source being connected to a drain of the fifth P-type transistor, and a drain being connected to the third circuit output terminal; and
the third pull-down circuit comprising:
a sixth N-type transistor, a gate being connected to a command address inversion signal, and a source being connected to the low-level voltage;
a seventh N-type transistor, a gate being connected to an inverted power-down enable signal, a source being connected to a drain of the sixth N-type transistor, and a drain being connected to the third circuit output terminal, wherein the inverted power-down enable signal is opposite to the power-down enable signal in level; and
an eighth N-type transistor, a gate being connected to an inverted mirror enable signal, a source being connected to the low-level voltage, and a drain being connected to the third circuit output terminal, wherein the inverted mirror enable signal is opposite to the mirror enable signal in level.

12. The buffer circuit according to claim 1, further comprising CA5 to CA11 buffer circuits, the CA5 to CA11 buffer circuits being the same as the CA0 to CA4 buffer circuits in circuit structure.

13. A memory, comprising:
the buffer circuit according to claim 1;
a command address buffer control circuit, connected to the buffer circuit, and configured to output a power-down enable signal to the buffer circuit; and
a decoder circuit, connected to the command address buffer control circuit, and configured to send a power-down exit command to the command address buffer control circuit.

14. The memory according to claim 13, further comprising:
an address mirror circuit, connected to the buffer circuit, and configured to send a mirror enable signal to the buffer circuit.

15. The memory according to claim 13, further comprising:
a command address inversion pin, connected to the buffer circuit, and configured to send a command address inversion signal to the buffer circuit.
